(19) United States
(12) Patent Application Publication
(10) Pub. No.: US 2024/0319770 A1
(43) Pub. Date: Sep. 26, 2024

(54) STRETCHABLE DISPLAY APPARATUS

(71) Applicants: Sungwoo Nam, Gwacheon-si (KR); Samsung Display Co., LTD., Yongin-si (KR)

(72) Inventors: Jangyeol YOON, Yongin-si (KR); Sungwoo NAM, Gwacheon-si (KR)

(21) Appl. No.: 18/610,972

(22) Filed: Mar. 20, 2024

(30) Foreign Application Priority Data
Mar. 20, 2023 (KR) 10-2023-0036163

(51) Int. Cl. G06F 1/16; H01L 25/075; H01L 33/62

(52) U.S. Cl. CPC G06F 1/1652; H01L 25/0753; H01L 33/62

(57) ABSTRACT

A stretchable display device includes: a substrate including: a first island area and a second island area, spaced apart from each other, and a connection area connected between the first island area and the second island area; a first subpixel circuit disposed in the first island area; a second subpixel circuit disposed in the second island area; a first light-emitting diode disposed in the first island area and electrically connected to the first subpixel circuit; a second light-emitting diode disposed in the second island area and electrically connected to the second subpixel circuit; and a wiring disposed in the connection area and electrically connected to the first subpixel circuit and the second subpixel circuit, where the wiring includes a first conductive layer including a conductive organic material, and a second conductive layer disposed on the first conductive layer and including a material different from that of the first conductive layer.

This application claims priority to Korean Patent Application No. 10-2023-0036163, filed on Mar. 20, 2023, and all the benefits accruing therefrom under 35 U.S.C. § 119, the content of which in its entirety is herein incorporated by reference.

### BACKGROUND

### 1. Field

One or more embodiments relate to a display device, for example, a stretchable display device.

### 2. Description of the Related Art

Due to the development of display devices configured to display image based on electrical signals in a visual manner, various display devices having desired characteristics such as small thickness, light weight, and low power-consumption have been introduced. For example, flexible display devices that may be bent or rolled have been introduced. Recently, there have been research and development on stretchable display devices that may be transformed into various shapes.

### SUMMARY

One or more embodiments of the disclosure relate to a structure of a display device, for example, a structure of a stretchable display device.

According to one or more embodiments, a stretchable display device includes a substrate including a first island area and a second island area, which are spaced apart from each other, and a connection area connected between the first island area and the second island area, a first subpixel circuit disposed in the first island area, a second subpixel circuit disposed in the second island area, a first light-emitting diode disposed in the first island area and electrically connected to the first subpixel circuit, a second light-emitting diode disposed in the second island area and electrically connected to the second subpixel circuit, and a wiring arranged in the connection area and electrically connected to the first subpixel circuit and the second subpixel circuit, where the wiring includes a first conductive layer including a conductive organic material and a second conductive layer including a material different from that of the first conductive layer.

In an embodiment, the first conductive layer may include a material having higher electrical conductivity than electrical conductivity of the material of the second conductive layer.

In an embodiment, the first conductive layer may include a conductive porous carbon material.

In an embodiment, the first conductive layer may include a laser-induced carbon material, and the second conductive layer may include at least one material selected from aluminum (Al), copper (Cu), titanium (Ti), platinum (Pt), and gold (Au).

In an embodiment, the stretchable display device may further include an organic insulating layer disposed under the wiring in the connection area.

In an embodiment, a least a portion of the wiring may directly contact the organic insulating layer.

In an embodiment, a thickness of a first portion of the organic insulating layer overlapping the wiring may be less than a thickness of a second portion of the organic insulating layer which does not overlap the wiring.

In an embodiment, a portion of the organic insulating layer may extend onto an inorganic insulating layer disposed in the first island area, and the organic insulating layer may include a step portion near an edge of the inorganic insulating layer.

In an embodiment, a thickness of a first portion of the first conductive layer on the step portion of the organic insulating layer may be greater than a thickness of a second portion of the first conductive layer apart from the step portion.

In an embodiment, the organic insulating layer may be provided with a contact hole defined therethrough in the first island area, and the wiring may be electrically connected to the first subpixel circuit through the contact hole.

In an embodiment, a portion of the first conductive layer of the wiring may be in the contact hole.

In an embodiment, at least a portion of the wiring may directly contact the substrate.

In an embodiment, the substrate may include an insulating polymer.

In an embodiment, when viewed in a direction perpendicular to the substrate, the first conductive layer of the wiring may be provided with a plurality of pattern holes apart from each other.

In an embodiment, the wiring may include a scan line, data line, or a voltage line electrically connected to the first subpixel circuit and the second subpixel circuit.

In an embodiment, the connection area may include a first area having a relatively high strain rate and a second area having a relatively low strain rate when the stretchable display device extends and a thickness of a portion of the wiring in the first area may be greater than a thickness of another portion of the wiring in the second area.

In an embodiment, the first area of the connection area may include a middle point of a longitudinal portion of the connection area.

In an embodiment, when viewed in a direction perpendicular to the substrate, the connection area may include a bent area, and the first area of the connection area may further include the bent area.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view schematically illustrating a stretchable display device (hereinafter, referred to as display device) according to an embodiment of the disclosure;

FIG. 2A is a perspective view of the display device shown in FIG. 1 in a first state in which the display device is elongated in a first direction;

FIG. 2B is a perspective view of the display device shown in FIG. 1 in a second state in which the display device is elongated in a second direction;

FIG. 3 is an equivalent circuit diagram schematically illustrating one light-emitting diode of a display device according to an embodiment of the disclosure and a subpixel circuit electrically connected to the light-emitting diode;

FIG. 4 is a top-plan view of an enlarged image of a portion of a display area of a display device according to an embodiment of the disclosure;

FIGS. 5A to 5C are cross-sectional views taken along line V-V′ shown in FIG. 4, each of which illustrates a portion of a display device according to an embodiment of the disclosure;

FIG. 6 is a cross-sectional view of an enlarged image of portion VI shown in FIG. 5A as a portion of a display device according to an embodiment of the disclosure;

FIG. 7 is a top-plan view of a portion selected from a display device according to an embodiment of the disclosure;

FIGS. 8A and 8B each are a cross-sectional view of a portion of a display device according to an embodiment of the disclosure, taken along line VIII-VIII′ shown in FIG. 7; and

FIG. 9 is a top-plan view of a connection portion selected from a display device according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof

It will be further understood that the terms “comprise,” “comprising,” “include,” “including,” “have,” “having,” and the like, when used herein, specify the presence of stated features and/or elements, but do not preclude the presence or addition of one or more other features and/or elements.

It will be understood that when an element is referred to as being “on” another element, it can be directly on the other element or intervening elements may be present therebetween. In contrast, when an element is referred to as being “directly on” another element, there are no intervening elements present.

In the drawings, the sizes of elements may be exaggerated or reduced for convenience of description. For example, since the size and thickness of each element is arbitrarily shown in the drawings for convenience of description, the disclosure is not necessarily limited to those illustrated.

When some embodiments may be differently implemented, a particular process sequence may be performed differently from a sequence described. For example, two processes described in succession may be performed substantially simultaneously, or may be performed in an order opposite to an order described.

In the present specification, when it is referred that a film, an area, and a component are connected to another film, area, and component, the film, area, and component may be directly connected to the other film, area, and component, or may be indirectly connected with another film, area, and component therebetween. For example, when it is referred that a film, an area, and a component are electrically connected to another film, area, and component, the film, area, and component may be directly in electric connection with the other film, area, and component, or may be indirectly in electric connection with the other film, area, and component with another film, area, and component therebetween.

An x-axis, a y-axis, and a z-axis are not limited to three axes on an orthogonal coordinate system, and may be interpreted as a wide meaning including the same. For example, the x-axis, y-axis, and z-axis may be orthogonal to one another, but may also refer to different directions that are not orthogonal to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

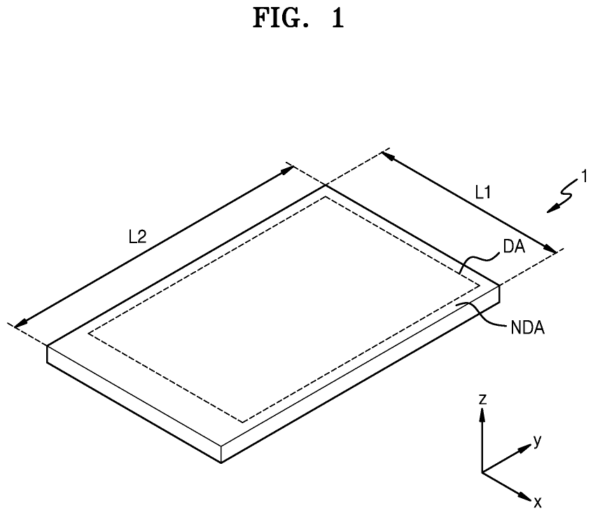

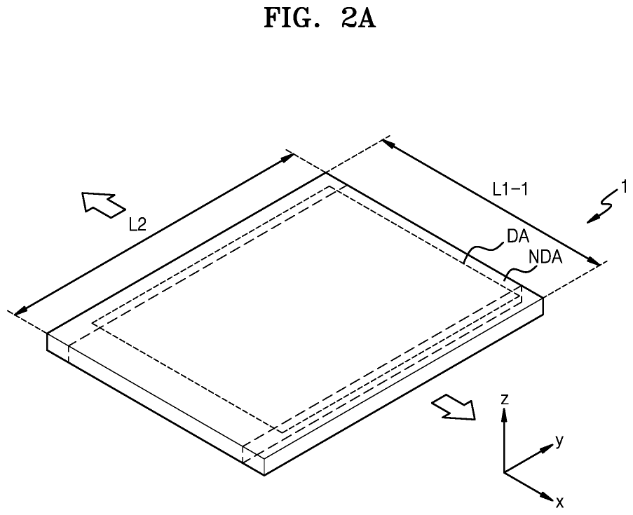

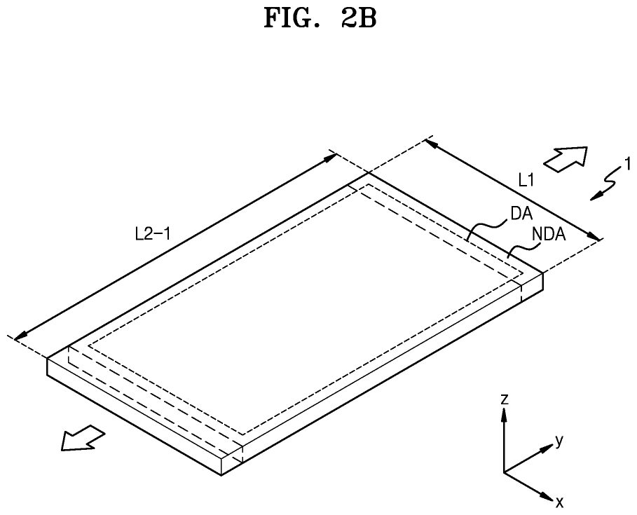

FIG. 1 is a perspective view schematically illustrating a stretchable display device 1 (hereinafter, referred to as a display device) according to an embodiment of the disclosure. FIG. 2A is a perspective view of the display device 1 shown in FIG. 1 in a first state in which the display device 1 is elongated in a first direction. FIG. 2B is a perspective view of the display device 1 shown in FIG. 1 in a second state in which the display device 1 is elongated in a second direction.

Referring to FIG. 1, an embodiment of the display device 1 may include a display area DA and a non-display area NDA. The display area DA may include a plurality of subpixels. The display device 1 may be configured to provide certain images using light emitted from the plurality of subpixels. The non-display area NDA may be adjacent to the display area DA. In an embodiment, the non-display area NDA may substantially surround the display area DA.

The display device 1 may include a first side L1 extending in the first direction and a second side L2 extending in the second direction. The first side L1 and the second side L2 may each include an edge of the display device 1. The first direction and the second direction may cross each other. In an embodiment, for example, the first direction and the second direction may together form an acute angle. in an alternative embodiment, for example, the first direction and the second direction may together form an obtuse angle or may be orthogonal to each other. Hereinafter, an embodiment in which the first direction includes x direction or −x direction and the second direction includes y direction or −y direction will be mainly described in detail.

The display device 1 may include a stretchable display device. In an embodiment, as shown in FIG. 2A, when a tensile force is applied in the first direction (e.g., the x direction or the −x direction), the display device 1 may be elongated in the first direction (e.g., the x direction or the −x direction). In such an embodiment, a length of a first side L1-1 shown in FIG. 2A may be greater than a length of the first side L1 shown in FIG. 1. The display area DA and the non-display area NDA may each be elongated in the first direction (e.g., the x direction or the −x direction). In an alternative embodiment, when a compressive force is applied to the display device 1 in the first direction (e.g., the x direction or −x direction), the display device 1 may be contracted in the first direction (e.g., the x direction or the −x direction). In such an embodiment, the length of the first side L1-1 shown in FIG. 2A may be less than the length of the first side L1 shown in FIG. 1. The display area DA and the non-display area NDA may each be contracted in the first direction (e.g., the x direction or the −x direction).

Referring to FIG. 2B, in an embodiment, when a tensile force is applied to the display device 1 in the second direction (e.g., the y direction or the −y direction), the display device 1 may be elongated in the second direction (e.g., the y direction or the −y direction). In such an embodiment, a length of a second side L2-1 shown in FIG. 2B may be greater than the length of the second side L2 shown in FIG. 1. The display area DA and the non-display area NDA may each be elongated in a second direction (e.g., y direction or −y direction). In an embodiment, when a compressive force is applied to the display device 1 in the second direction (e.g., the y direction or the −y direction), the display device 1 may be contracted in the second direction (e.g., the y direction or the −y direction). In such an embodiment, the length of the second side L2-1 shown in FIG. 2B may be less than the length of the second side L2 shown in FIG. 1. The display area DA and the non-display area NDA may each be contracted in the second direction (e.g., the y direction or the −y direction). Like this, when a tensile force or a compressive force is applied to the display device 1, the display device 1 may be variously transformed.

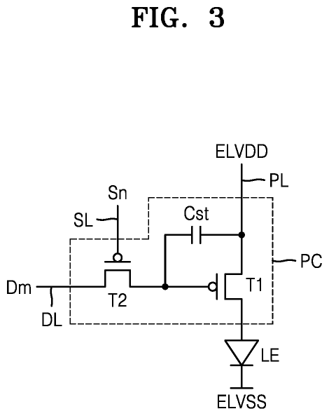

FIG. 3 is an equivalent circuit diagram schematically illustrating one light-emitting diode LE of the display device 1 according to an embodiment of the disclosure and a subpixel circuit PC electrically connected to the light-emitting diode LE.

Referring to FIG. 3, in an embodiment, the subpixel circuit PC electrically connected to the light-emitting diode LE may include a driving transistor T1, a switching transistor T2, and a storage capacitor Cst.

The switching transistor T2 may be connected to a scan line SL and a data line DL, and may be configured to deliver a data signal Dm input from the data line DL to the driving transistor T1, in response to a scan signal Sn input from the scan line SL.

The storage capacitor Cst may be connected to the switching transistor T2 and a driving voltage line PL, and may be configured to store a voltage corresponding to a difference between a voltage received from the switching transistor T2 and a first power voltage ELVDD provided to the driving voltage line PL.

The driving transistor T1 may be connected to the driving voltage line PL and the storage capacitor Cst, and may be configured to control a driving current flowing from the driving voltage line PL through the light-emitting diode LE to correspond to a value of the voltage stored in the storage capacitor Cst. The light-emitting diode LE may be configured to emit light having a certain luminance corresponding to the driving current. A counter electrode (e.g., a cathode) of the light-emitting diode LE may receive a second power voltage ELVSS.

Although FIG. 3 illustrates an embodiment where the subpixel circuit PC includes two transistors and one storage capacitor, in an alternative embodiment, the subpixel circuit PC may include three or more transistors.

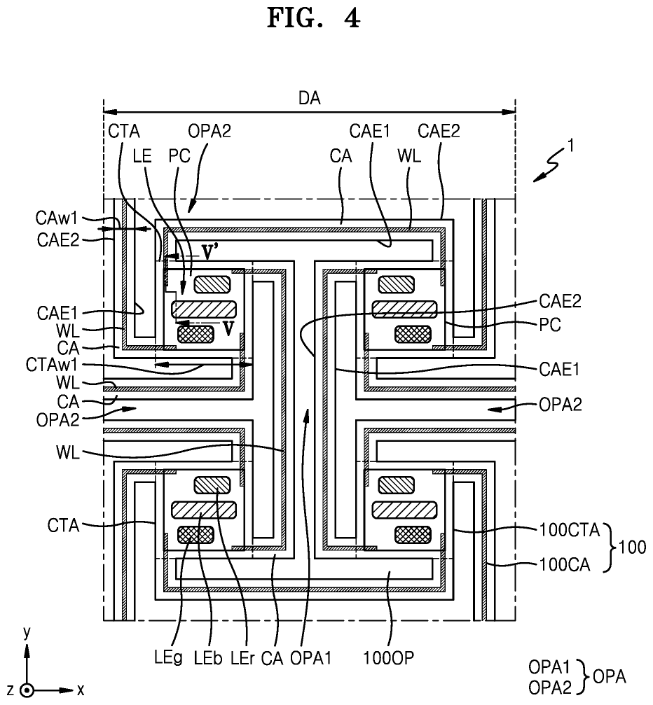

FIG. 4 is a top-plan view of an enlarged image of a portion of the display area DA of the display device 1 according to an embodiment of the disclosure.

Referring to FIG. 4, an embodiment of the display device 1 may include island portions CTA, connection portions CA, and opening portions OPA.

The island portions CTA, in which the light-emitting diodes LE are arranged, may be spaced apart from one another. FIG. 4 illustrates a portion of an embodiment where a red light-emitting diode LEr, a green light-emitting diode LEg, and a blue light-emitting diode LEb are arranged in each island portion CTA.

The connection portion CA may extend between the island portions CTA adjacent to each other. The connection portion CA may connect the island portions CTA adjacent to each other.

FIG. 4 illustrates an embodiment where each island portion CTA is connected to four connection portions CA. The four connection portions CA connected one island portion CTA respectively extend in different directions from each other, and each of the connection portions CA may be connected to corresponding one of the others island portion CTA arranged adjacent to the island portion CTA described above. In an embodiment, for example, one island portion CTA may be connected to four island portions CTA arranged in a direction surrounding the island portion CTA through the four connection portions CA, respectively. The island portions CTA adjacent to each other and the connection portion CA may be integrally connected to each other. In an embodiment, the island portions CTA and the connection portion CA may be integrally formed with each other as a single unitary and indivisible part.

Each connection portion CA may extend in a longitudinal direction of the connection portion CA to connect neighboring island portions CTA on a plane. Each connection portion CA may be bent. In an embodiment, for example, any one connection portion CA shown in FIG. 4 may be bent from the second direction (e.g. the y direction or the −y direction) in the first direction (e.g., the x direction or the −x direction) and then may be bent in a reverse second direction (e.g., the −y direction or the +y direction). Another connection portion CA may be bent from the first direction (e.g. the x direction or the −x direction) in the second direction (e.g., the y direction or the −y direction) and then may be bent in a reverse first direction (e.g., the −x direction or the +x direction). Although FIG. 4 illustrates an embodiment where a corner of a bent portion of the connection portion CA has a right angle, in an alternative embodiment, the bent portion of the connection portion CA may have various angles. In an embodiment, the bent portion of the connection portion CA may have a rounded shape.

A direction in which the connection portion CA is bent may indicate the longitudinal direction of the connection portion CA. The connection portion CA may have a width CAw1 that is less than a length of extension between the island portions CTA adjacent to each other. The width CAw1 of the connection portion CA may be less than a width CTAw1 of the island portion CTA. A length of the connection portion CA may be defined as a value obtained by dividing a sum of lengths of a first side CAE1 and a second side CAE2 of the connection portion CA by two, and the width CAw1 of the connection portion CA indicates a value in a direction perpendicular to the length of the connection portion CA. The first side CAE1 of the connection portion CA may be relatively adjacent to the island portion CTA, and the second side CAE2 may indicate a side opposite the first side CAE1 and relatively distant from the island portion CTA. In other words, the first side CAE1 of the connection portion CA is a side relatively adjacent to the island portion with reference to a wiring WL, and the second side CAE2 may indicate a side relatively distant from the island portion CTA with reference to the wiring WL.

Each connection portion CA may include the wiring WL. The wiring WL may be electrically connected to the subpixel circuit PC in each of the island portions CTA at two sides of a corresponding connection portion CA. In an embodiment, for example, the wiring WL arranged in the connection portion CA between the island portions CTA adjacent to each other may be electrically connected to the subpixel circuit PC in any one island portion CTA and the subpixel circuit PC in another island portion CTA between the island portions CTA adjacent to each other. The subpixel circuit PC in each island portion CTA may include a transistor and a capacitor as described above with reference to FIG. 3.

The wiring WL may include a signal line (e.g., a scan line SL and a data line DL shown in FIG. 3) or a voltage line (e.g., a driving voltage line PL shown in FIG. 3) configured to provide a signal or a voltage to the subpixel circuit PC connected to the wiring WL. A width of the wiring WL may be smaller than the width CAw1 of the connection portion CA.

Although FIG. 4 illustrates an embodiment where each connection portion CA includes one wiring WL, the disclosure is not limited thereto. In an alternative embodiment, each connection portion CA may include a plurality of wirings WL.

The opening portions OPA may correspond to a kind of through holes defined through the display device 1. Each opening portion OPA may be surrounded by four island portions CTA and four connection portions CA. Each opening portion OPA may be defined by four island portions CTA and four connection portions CA. In an embodiment, for example, each opening portion OPA may be surrounded or defined by a respective side of the corresponding four island portions CTA and a respective side of the corresponding four connection portions CA, on a plane or in a plan view. Each opening portion OPA may have a shape obtained by rotating alphabet “H” by about 90 degrees or a shape such as alphabet “H”.

The opening portions OPA may be apart from each other. In an embodiment, as illustrated in FIG. 4, opening portions (hereinafter, referred to as first opening portion OPA1) having the shape obtained by rotating alphabet “H” by about 90 degrees and opening portions (hereinafter, referred to as second opening portion OPA2) having the shape such as alphabet “H” are alternately arranged in the ±x directions and the ±y directions. In the specification, the opening portion OPA may indicate the first opening portion OPA1 and/or the second opening portion OPA2.

As described above with reference to FIGS. 2A and 2B, when a force is applied to the display device 1, as the shape of the opening portion OPA, i.e., the first opening portion OPA1 and/or the second opening portion OPA2 changes, occurrence of a stress during transformation of the display device 1 may be easily reduced, such that abnormal transformation of the display device 1 may be effectively prevented, and the durability of the display device 1 may be substantially improved.

A structure of the display device 1 shown in FIG. 4, including the island portions CTA, the connection portions CA, and the opening portions OPA, may include a form of the substrate 100 provided in the display device 1. In an embodiment, for example, the substrate 100 may include island areas 100CTA corresponding to the island portions CTA described above, connection areas 100CA corresponding to the connection portions CA described above, and openings 100OP corresponding to the opening portions OPA.

The island areas 100CTA of the substrate 100 may be apart from each other and may be connected to each other by the connection areas 100CA. The connection area 100CA may extend between the island areas 100CTA adjacent to each other, and may be integral with the island area 100CTA.

Descriptions of features of the island portions CTA, the connection portions CA, and the opening portions OPA of the display device 1 described with reference to FIG. 4 may be considered as descriptions of features of the island areas 100CTA, the connection areas 100CA, and the openings 100OP of the substrate 100. In other words, the descriptions of the connection portion CA may correspond to the descriptions of the connection area 100CA of the substrate 100, and the descriptions of the opening portions OPA may correspond to the description of the openings 100OP of the substrate 100. In an embodiment, for example, when a length of the connection portion CA is greater than the width CAw1 of the connection portion CA, it may be considered that a length of the connection area 100CA of the substrate 100 is greater than a width of the connection area 100CA of the substrate 100. Here, as described above, the width indicates a value in a direction perpendicular to a length.

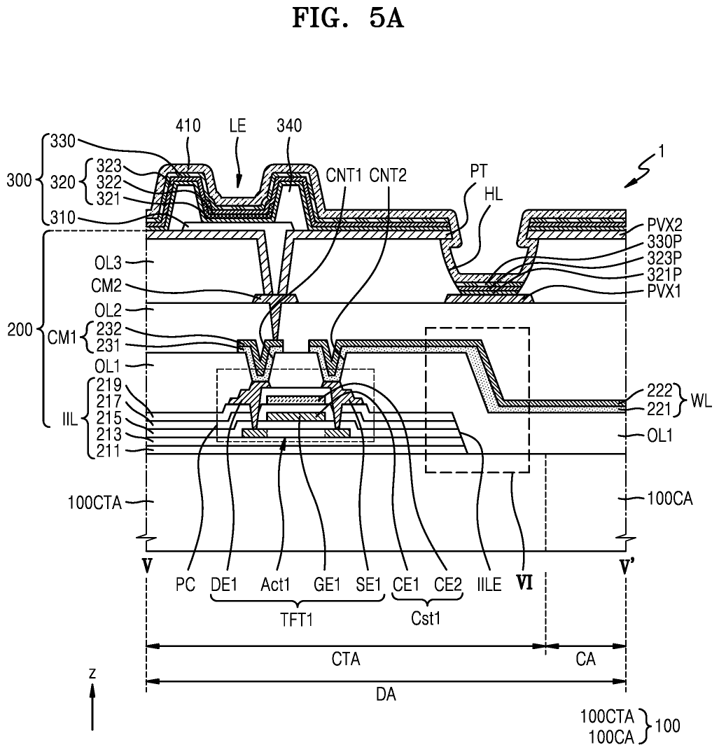

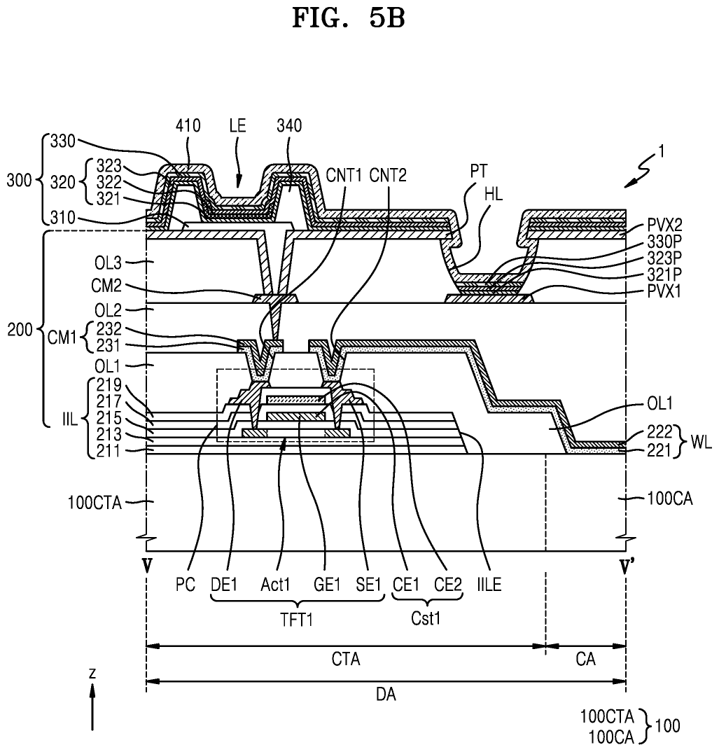

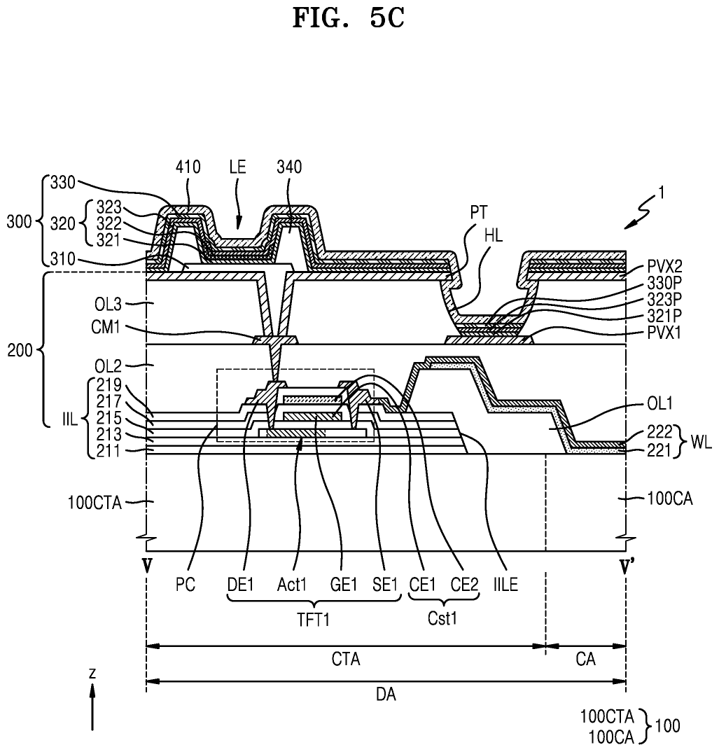

FIGS. 5A to 5C are cross-sectional views taken along line V-V′ shown in FIG. 4, each of which illustrates a portion of the display device 1 according to an embodiment of the disclosure.

Referring to FIG. 5A, in an embodiment, the display area DA of the display device 1 may include the island portion CTA and the connection portion CA, and the island portion CTA may include the light-emitting diode LE and the subpixel circuit PC electrically connected to the light-emitting diode LE. The subpixel circuit PC may be arranged between the substrate 100 and the light-emitting diode LE, e.g., the island area 100CTA of the substrate 100 and the light-emitting diode LE.

The substrate 100 may include an organic insulating material such as a polymer. The substrate 100 may include a polymer such as polyether sulfone, polyarylate, polyetherimide, polyethylene naphthalate, polyethylene terephthalate, polyphenylene sulfide, polyimide, polycarbonate, cellulose triacetate or cellulose acetate propionate. In an embodiment, the substrate 100 may have a multiple-layer structure including a base layer including the aforementioned polymers and a barrier layer including an inorganic insulating material. The substrate 100 including a polymer resin may be flexible, rollable, and bendable.

A circuit layer 200 may be disposed on the substrate 100. The circuit layer 200 may include the subpixel circuit PC, an inorganic insulating layer IIL, a first organic insulating layer OL1, a second organic insulating layer OL2, a first contact electrode CM1, a third organic insulating layer OL3, a first inorganic layer PVX1, and a second inorganic layer PVX2. The subpixel circuit PC may include a first transistor TFT1 and a first storage capacitor Cst1. The first transistor TFT1 may include a first semiconductor layer Act1, a first gate electrode GE1, a first source electrode SE1, and a first drain electrode DE1. The first storage capacitor Cst1 may include a first capacitor electrode CE1 and a second capacitor electrode CE2.

The inorganic insulating layer IIL may be disposed on the substrate 100. The inorganic insulating layer IIL may include a barrier layer 211, a buffer layer 213, a first gate insulating layer 215, a second gate insulating layer 217, and/or an interlayer insulating layer 219.

The barrier layer 211 may be disposed on the substrate 100, e.g., on the island area 100CTA of the substrate 100. The barrier layer 211 may be a layer for preventing or reducing permeation of foreign impurities. The barrier layer 211 may include or be defined by a single layer or multiple layers including an inorganic insulating material such as silicon nitride, silicon oxide, and/or silicon oxynitride.

The buffer layer 213 may be disposed on the barrier layer 211. The buffer layer 213 may include or be defined by a single layer or multiple layers including an inorganic insulating material such as silicon nitride, silicon oxide, and/or silicon oxynitride.

The first semiconductor layer Act1 may be disposed on the buffer layer 213. The first semiconductor layer Act1 may include polysilicon. Alternatively, the first semiconductor layer Act1 may include amorphous silicon, an oxide semiconductor, an organic semiconductor, or the like. In an embodiment, the first semiconductor layer Act1 may include a channel area, and may also include a source area and a drain area respectively arranged at two sides of the channel area.

The first gate insulating layer 215 may be disposed on the first semiconductor layer Act1 and the buffer layer 213. The first gate insulating layer 215 may include an inorganic insulating material such as silicon oxide, silicon nitride, silicon oxynitride, aluminum oxide, titanium oxide, tantalum oxide, hafnium oxide, zinc oxide, or the like. Here, zinc oxide may include zinc oxide (ZnO) and/or zinc peroxide (ZnO₂).

The first gate electrode GE1 may be disposed on the first gate insulating layer 215. The first gate electrode GE1 may overlap the channel area of the first semiconductor layer Act1. The first gate electrode GE1 may include a low-resistance metal material. In an embodiment, the first gate electrode GE1 may include a conductive material including molybdenum (Mo), aluminum (Al), copper (Cu), titanium (Ti), or the like, and may be defined by multiple layers or a single layer including at least one selected from the aforementioned materials.

The second gate insulating layer 217 may be disposed on the first gate electrode GE1 and the first gate insulating layer 215. The second gate insulating layer 217 may include an inorganic insulating material including silicon nitride, silicon oxide, and/or silicon oxynitride.

The second capacitor electrode CE2 may be disposed on the second gate insulating layer 217. The second capacitor electrode CE2 may overlap the first gate electrode GE1. In this case, the first gate electrode GE1 may function as the first capacitor electrode CE1. Although FIG. 5A illustrates an embodiment where the first storage capacitor Cst1 and the first transistor TFT1 overlap each other, in an alternative embodiment, the first storage capacitor Cst1 and the first transistor TFT1 may not overlap each other. In this case, the first capacitor electrode CE1 and the first gate electrode GE1 may be separate electrodes. The second capacitor electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be defined by a single layer or multiple layers including at least one selected from the aforementioned materials.

The interlayer insulating layer 219 may be disposed on the second capacitor electrode CE2 and the second gate insulating layer 217. The interlayer insulating layer 219 may include an inorganic insulating material such as silicon oxide, silicon nitride, silicon oxynitride, or the like.

Each of the first source electrode SE1 and the first drain electrode DE1 may be disposed on the interlayer insulating layer 219. The first source electrode SE1 and the first drain electrode DE1 may each be connected to the first semiconductor layer Act1 through a contact hole provided (e.g., formed or defined) in the first gate insulating layer 215, the second gate insulating layer 217, and the interlayer insulating layer 219. At least one selected from the first source electrode SE1 and the first drain electrode DE1 may include a conductive material including Mo, Al, Cu, Ti, Pt, and/or Au, and may be defined by a single layer or multiple layers including at least one selected from the aforementioned materials. In an embodiment, the first source electrode SE1 and/or the first drain electrode DE1 may have a multiple-layer structure including Ti/AI/Ti.

In an embodiment, in the display area DA, the inorganic insulating layer IIL may overlap the island area 100CTA of the substrate 100 and may not overlap the connection area 100CA of the substrate 100. The inorganic insulating layer IIL may have an end portion (or an edge) IILE of the inorganic insulating layer IIL facing the connection area 100CA. In other words, the connection portion CA may not include the inorganic insulating layer IIL that is relatively fragile to cracks, and accordingly, in elongation and contraction of the display device 1, damages to the connection portion CA transformed in a relatively high degree may be effectively prevented.

The first organic insulating layer OL1 may be disposed on the island area 100CTA and the connection area 100CA of the substrate 100 and may cover the end portion (or the edge) IILE of the inorganic insulating layer IIL. The first organic insulating layer OL1 may minimize a height difference when the wiring WL extends from the island area 1000T of the substrate 100 to the connection portion CA. The first organic insulating layer OL1 may absorb a stress that may be applied to the wiring WL. The first organic insulating layer OL1 may include an organic insulating material. The first organic insulating layer OL1 may include an organic insulating material including a general-purpose polymer such as polymethylmethacrylate (PMMA) or polystyrene (PS), a polymer derivative having a phenol group, an acryl-based polymer, an imide-based polymer such as polyimide, an amide-based polymer, a fluoride-based polymer, a p-xylene-based polymer, a vinylalcohol-based polymer, or blends thereof.

The wiring WL may be electrically connected to the subpixel circuits PC arranged in the island portion CTA. The wiring WL may have a multiple-layer structure including a first conductive layer 221 including a conductive organic material and a second conductive layer 222 located on the first conductive layer 221 and including a material different from that of the first conductive layer 221.

The first conductive layer 221 may include a conductive organic material including carbon atoms and having electrical conductivity. The second conductive layer 222 may include at least one metal material selected from Al, Cu, Ti, Pt, and Au.

The first conductive layer 221 may include a material having electrical conductivity greater than electrical conductivity of the material included in the second conductive layer 222. In an embodiment, for example, the first conductive layer 221 may include a conductive porous carbon material. In an embodiment, the first conductive layer 221 may include a laser-induced carbon material. In such an embodiment, the laser-induced carbon material may include laser-induced graphene (LIG). The first conductive layer 221 having porosity may have impact resistance better than that of the second conductive layer 222. In an embodiment, for example, the first conductive layer 221 may be defined by a single layer including LIG or have a multiple-layer structure in which a plurality of LIG layers are stacked.

In embodiments of the disclosure, since the wiring WL includes or is defined by a plurality of layers, e.g., two layers having different characteristics from each other, it is possible to prevent a damage and/or a disconnection of the wiring WL even if a stress is applied to the connection portion CA. In a conventional case, where the wiring WL is a layer only including a metal, the wiring WL may be disconnected when cracks are formed on the wiring WL due to stress when the display device 1 is elongated.

According to an embodiment of the disclosure, as the wiring WL includes the first conductive layer 221 and the second conductive layer 222 respectively having different features from each other and including different materials from each other, the cracks may be prevented from being formed on the wiring WL due to stress when the display device 1 is elongated. In an embodiment, for example, the first conductive layer 221 may have relatively high impact resistance due to the porosity thereof and may absorb the impacts applied to the second conductive layer 222, and thus, occurrence of cracks on the wiring WL due to stress may be reduced. In addition, when the stress causes cracks on the second conductive layer 222 and then the disconnection of the second conductive layer 222 occurs, currents/signals may be delivered through the first conductive layer 221 contacting the second conductive layer 222, and therefore, functions of the wiring WL may be maintained.

In an embodiment, where the second conductive layer 222 is a metal layer including at least one selected from the aforementioned metals and the first conductive layer 221 includes a porous carbon material, a density (a degree of being dense) of the wiring WL in a direction from the second conductive layer 222 toward the first conductive layer 221 (e.g., −z direction) may decrease based on an interface at which the second conductive layer 222 and the first conductive layer 221 contact each other.

In an embodiment, as shown in FIG. 5A, the wiring WL may directly contact the first organic insulating layer OL1. In an embodiment, for example, a lowermost layer of the wiring WL, i.e., the first conductive layer 221, may directly contact the first organic insulating layer OL1.

In an alternative embodiment, as shown in FIG. 5B, the first organic insulating layer OL1 may cover the end portion IILE of the inorganic insulating layer IIL and may not extend in the longitudinal direction of the connection portion CA. In an embodiment, for example, the first organic insulating layer OL1 may not overlap a portion of the connection portion CA, and the wiring WL may directly contact the first organic insulating layer OL1 and the substrate 100. A portion of the wiring WL may directly contact the first organic insulating layer OL1 and another portion of the wiring WL may directly contact the substrate 100 including a polymer. In an embodiment, for example, the other portion of the wiring WL may directly contact a polymer material layer of the substrate 100.

The first conductive layer 221 of the wiring WL may be formed by radiating laser on a layer including an organic material. In an embodiment, where the first organic insulating layer OL1 extends in the longitudinal direction of the connection portion CA as shown in FIG. 5A, laser may be radiated in a longitudinal direction of the first organic insulating layer OL1, and the first conductive layer 221 of the wiring WL may contact the first organic insulating layer OL1. In an alternative embodiment, where the first organic insulating layer OL1 overlaps a portion of the connection portion CA and the substrate 100 including a polymer is disposed under the first organic insulating layer OL1 as shown in FIG. 5B, the laser may be radiated onto the first organic insulating layer OL1 and a polymer layer of the substrate 100. The wiring WL formed by the aforementioned laser may directly contact the first organic insulating layer OL1 and the substrate 100.

The second organic insulating layer OL2 may be disposed on the wiring WL. The second organic insulating layer OL2 may include an organic material. The second organic insulating layer OL2 may include an organic insulating material including a general-purpose polymer such as polymethylmethacrylate (PMMA) or polystyrene (PS), a polymer derivative having a phenol group, an acryl-polymer polymer, an imide-based polymer such as polyimide, an amide-based polymer, a fluoride-based polymer, a p-xylene-based polymer, a vinylalcohol-based polymer, or blends thereof.

In the connection area 100CA of the substrate 100, the wiring WL may be between the first organic insulating layer OL1 and the second organic insulating layer OL2. When the display device 1 transformed, the connection area 100CA of the substrate 100 may be transformed. In this case, a stress neutral plane may exist in the display device 1. As the wiring WL is disposed between the first organic insulating layer OL1 and the second organic insulating layer OL2, at least a portion of the wiring WL may be on the stress neutral plane, and the stress applied to the wiring WL may be effectively reduced.

The first contact electrode CM1 may be disposed on the first organic insulating layer OL1. The first contact electrode CM1 may be electrically connected to the subpixel circuit PC through a first contact hole CNT1 of the first organic insulating layer OL1. In an embodiment, the first contact electrode CM1 may include a same material and have a same stack structure as the wiring WL. In an embodiment, for example, the first contact electrode CM1 may include a first electrode layer 231 and a second electrode layer 232. The first electrode layer 231 and the second electrode layer 232 of the first contact electrode CM1 may include a same material as that of the first conductive layer 221 and the second conductive layer 222 of the wiring WL. In an embodiment, for example, the first contact hole CNT of the first organic insulating layer OL1 may be at least partially filled by a portion of a material corresponding to the first electrode layer 231 of the first contact electrode CM1, e.g., a portion of the porous carbon material (e.g., the LIG).

The first conductive layer 221 of the wiring WL may be electrically connected to the subpixel circuit PC, e.g., the first source electrode SE1 of the first transistor TFT1, through a second contact hole CNT2 formed in the first organic insulating layer OL1. In an embodiment, for example, at least a portion of a second contact hole CNT2 of the first organic insulating layer OL1 may be at least partially filled by the material corresponding to the first conductive layer 221 of the wiring WL (e.g., the porous carbon material such as LIG).

The second organic insulating layer OL2 may be disposed on the first organic insulating layer OL1. A second contact electrode CM2 may be electrically connected to the first contact electrode CM1 through a contact hole of the second organic insulating layer OL2. The third organic insulating layer OL3 may be disposed on the second organic insulating layer OL2 and the second contact electrode CM2. The second organic insulating layer OL2 and the third organic insulating layer OL3 may each include an organic material. The second organic insulating layer OL2 and the third organic insulating layer OL3 may each include a general-purpose polymer such as polymethylmethacrylate (PMMA) or polystyrene (PS), a polymer derivative having a phenol group, an acryl-based polymer, an imide-based polymer such as polyimide, an amide-based polymer, a fluoride-based polymer, a p-xylene-based polymer, a vinylalcohol-based polymer, or blends thereof.

The first inorganic layer PVX1 may be disposed between the second organic insulating layer OL2 and the third organic insulating layer OL3. The first inorganic layer PVX1 may include an inorganic material (e.g., an inorganic insulating material).

The third organic insulating layer OL3 may be provided with a hole HL. The hole HL may expose the first inorganic layer PVX1. The hole HL may be formed by etching the third organic insulating layer OL3, and the first inorganic layer PVX1 may effectively prevent or substantially reduce over-etching on components under the first inorganic layer PVX1.

The second inorganic layer PVX2 may include an inorganic insulating material and may be disposed on the third organic insulating layer OL3. The second inorganic layer PVX2 may have a protrusion tip PT protruding toward a center of the hole HL. A bottom surface of the protrusion tip PT of the second inorganic layer PVX2 may be exposed through the hole HL.

A light-emitting diode layer 300 may be disposed on the circuit layer 200. The light-emitting diode layer 300 may include the light-emitting diode LE and a bank layer 340. The light-emitting diode LE may include an organic light-emitting diode. The light-emitting diode LE may include a first electrode 310, an intermediate layer 320, and a second electrode 330 that is a counter electrode.

The first electrode 310 of the light-emitting diode LE may be electrically connected to the second contact electrode CM2 through a contact hole of the third organic insulating layer OL3. In an embodiment, the first electrode 310 may include a conductive oxide material such as indium tin oxide (ITO), indium zinc oxide (IZO), zinc oxide (ZnO), indium oxide (In₂O₃), indium gallium oxide (IGO), or aluminum zinc oxide (AZO). In an alternative embodiment, the first electrode 310 may include a reflective film including Ag, Mg, Al, Pt, Pd, Au, Ni, Nd, Ir, Cr, or compounds thereof. In another alternative embodiment, the first electrode 310 may include a film including ITO, IZO, ZnO, or In₂O₃ on/under the aforementioned reflective film.

The bank layer 340 may cover an edge of the first electrode 310. The bank layer 340 may be provided with an emission opening, and the emission opening may overlap the first electrode 310. The emission opening may define an emission area of light emitted from the light-emitting diode LE. The bank layer 340 may include an organic insulating material and/or an inorganic insulating material. In some embodiments, the bank layer 340 may include a light-blocking material.

The intermediate layer 320 may be disposed on the first electrode 310, the bank layer 340, and/or the second inorganic layer PVX2. The intermediate layer 320 may include an emission layer 322. The emission layer 322 may overlap the first electrode 310. The emission layer 322 may include a high-molecular or low-molecular organic material emitting light having certain colors.

The intermediate layer 320 may further include a first function layer 321 and/or a second function layer 323. The first function layer 321 may be disposed between the first electrode 310 and the emission layer 322. The first function layer 321 may include a hole transport layer (HTL) and/or a hole injection layer (HIL). The second function layer 323 may be disposed between the emission layer 322 and the second electrode 330. The second function layer 323 may include an electron transport layer (ETL) and/or an electron injection layer (EIL). In an embodiment, the first function layer 321 and the second function layer 323 may generally overlap the island area 100CTA and the connection area 100CA of the substrate 100.

The second electrode 330 may be disposed on the first electrode 310, the intermediate layer 320, and the bank layer 340. The second electrode 330 may include a conductive material having a small work function. In an embodiment, for example, the second electrode 330 may include a (semi) transparent layer including Ag, Mg, Al, Pt, Pd, Au, Ni, Nd, Ir, Cr, Li, Ca or alloys thereof. Alternatively, the second electrode 330 may further include a layer including ITO, IZO, ZnO or In₂O₃ on the (semi) transparent layer including the aforementioned materials.

Organic materials included in the intermediate layer 320, e.g., the first function layer 321 and the second function layer 323, may be disconnected by the protrusion tip PT. The first function layer 321 and the second function layer 323 including organic materials may be function as a path into which oxygen or moisture from outside may permeate. In an embodiment, the second inorganic layer PVX2 has the protrusion tip PT protruding toward the center of the hole HL, and accordingly, the first function layer 321 and the second function layer 323 may each be blocked due to the hole HL. Accordingly, introduction of moisture or oxygen moving from the outside toward the light-emitting diode LE may be effectively prevented or substantially reduced.

In an embodiment, a first dummy function layer 321P including a same material as that of the first function layer 321 and/or a second dummy function layer 323P including a same material as that of the second function layer 323. In an embodiment, a dummy counter electrode 330P including a same material as that of the second electrode 330 may be disposed on the first dummy function layer 321P and/or the second dummy function layer 323P.

An inorganic encapsulation layer 410 may be disposed on the light-emitting diode layer 300. The inorganic encapsulation layer 410 may generally cover the substrate 100. In an embodiment, for example, the inorganic encapsulation layer 410 may sequentially and generally overlap the island area 100CTA and the connection area 100CA of the substrate 100. The inorganic encapsulation layer 410 may directly contact the bottom surface of the protrusion tip PT of the second inorganic layer PVX2. Accordingly, introduction of moisture or oxygen from the outside into the light-emitting diode LE may be effectively prevented or substantially reduced.

In some embodiments, an organic encapsulation layer may be disposed on the inorganic encapsulation layer 410 to overlap the light-emitting diode LE. Furthermore, additional inorganic encapsulation layers may be further disposed on the organic encapsulation layer.

Although FIGS. 5A and 5B illustrate embodiments where the first conductive layer 221 and the second conductive layer 222 of the wiring WL have a substantially same length as each other, the disclosure may be not limited thereto. in an alternative embodiment, as shown in FIG. 5C, the wiring WL may include the first conductive layer 221 and the second conductive layer 222, and a length of the second conductive layer 222 may be greater than a length of the first conductive layer 221. In an embodiment, for example, the second conductive layer 222 may further extend to pass an end portion of the first conductive layer 221 and contact a top surface of the first organic insulating layer OL1. As the second conductive layer 222 of the wiring WL is electrically connected to an electrode (e.g., the first source electrode SE1) of the first transistor TFT1, the wiring WL may be electrically connected to the first transistor TFT1. In an embodiment, as shown in FIG. 5C, the second conductive layer 222 of the wiring WL may be integral with the electrode (e.g., the first source electrode SE1) of the first transistor TFT1. That is, the second conductive layer 222 of the wiring WL may be integrally formed with the electrode (e.g., the first source electrode SE1) as a single unitary and indivisible part.

In an embodiment, the first organic insulating layer OL1 may extend onto the subpixel circuit PC including the first transistor TFT1 and generally cover the island portion CTA as shown in FIGS. 5A and 5B, but the disclosure is not limited thereto. In an alternative embodiment, as shown in FIG. 5C, a portion of the first organic insulating layer OL1 may extend from the connection portion CA toward the island portion CTA to cover the end portion (or the edge) IILE of the inorganic insulating layer IIL, and may only overlap a portion of the island portion CTA.

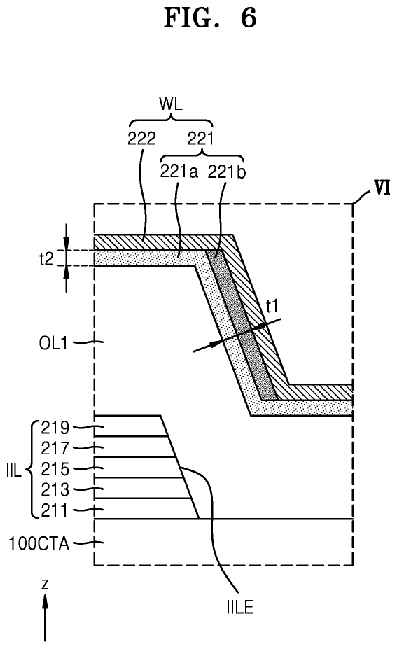

FIG. 6 is a cross-sectional view of an enlarged image of portion VI shown in FIG. 5A as a portion of the display device 1 according to an embodiment of the disclosure.

Referring to FIG. 6, the wiring WL may include the first conductive layer 221 and the second conductive layer 222, and the first conductive layer 221 may not have a uniform thickness. In an embodiment, for example, a first thickness t1 of a portion (hereinafter, referred to as a first portion) of the first conductive layer 221 may be greater than a second thickness t2 of another portion (hereinafter, referred as a second portion).

In an embodiment, as shown in FIG. 6, the first organic insulating layer OL1 extends to cover the end portion (or the edge) IILE of the inorganic insulating layer IIL, and around the end portion (or the edge) IILE of the inorganic insulating layer IIL, the first organic insulating layer OL1 may have a step portion (or a step structure). An area around the step portion of the first organic insulating layer OL1 may be fragile to the stress applied when the display device 1 is elongated. The first portion of the first conductive layer 221 having the first thickness t1 may be disposed on the step portion of the first organic insulating layer OL1, and the second portion of the first conductive layer 221 having the second thickness t2 may be arranged relatively distant from the step portion described above.

On the step portion of the first organic insulating layer OL1 (or a side surface corresponding to the edge of the inorganic insulating layer IIL), the first conductive layer 221 may have a stack structure including a first sub-conductive layer 221a and a second sub-conductive layer 221b. The first sub-conductive layer 221a and the second sub-conductive layer 221b may each include a conductive porous carbon material. In an embodiment, for example, the first sub-conductive layer 221a and the second sub-conductive layer 221b may each include laser induced graphene (LIG).

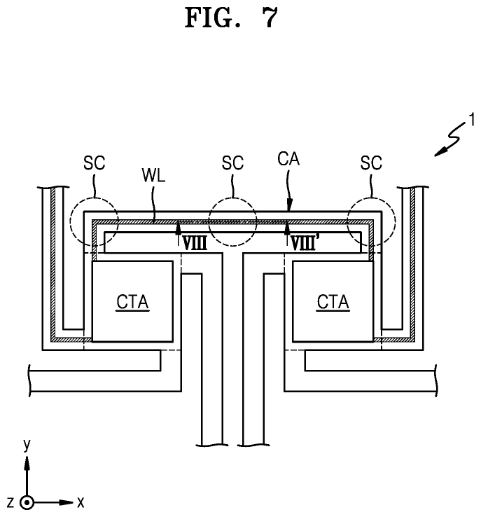

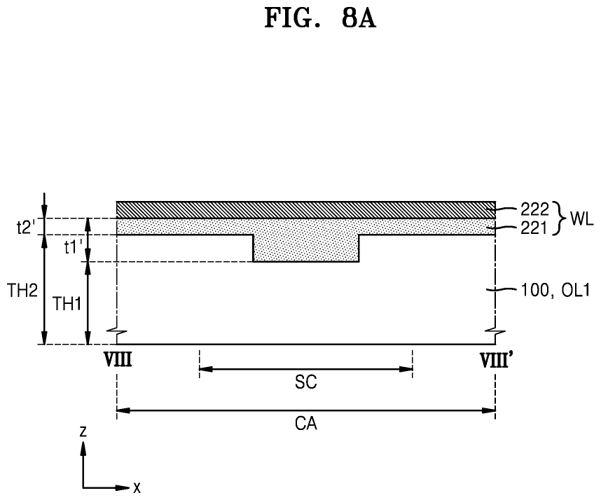

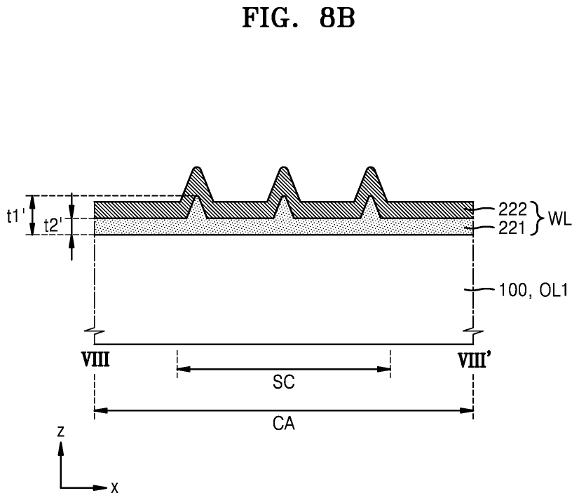

FIG. 7 is a top-plan view of an extracted image of a portion of the display device 1 according to an embodiment of the disclosure; and FIGS. 8A and 8B are each a cross-sectional view of a portion of the display device 1 according to an embodiment of the disclosure, taken along line VIII-VIII′ shown in FIG. 7.

Referring to FIGS. 7 to 8B, the connection portion CA between the island portions CTA of the display device 1 may include a local area fragile to stress (hereinafter, referred to as a stress-fragile area SC). In an embodiment, as shown in FIG. 7, the bent area of the connection portion CA and an area around a point of about ½ (i.e., a middle point) of the longitudinal (i.e., linear or straight) portion of the connection portion CA may be the stress-fragile areas SC which are fragile to stress when the display device 1 is elongated. For example, the stress-fragile areas SC of the connection portion CA may be also referred to as a first area having a relatively high strain rate, and an area except the stress-fragile areas SC of the connection portion CA may be also referred to as a second area having a relatively low strain rate.

A thickness of a portion of the wiring WL arranged in the stress-fragile area SC described above may be greater than a thickness of another portion of the wiring WL. In an embodiment, for example, as shown in FIGS. 8A and 8B, the wiring WL may include the first conductive layer 221 and the second conductive layer 222, and a thickness t1′ of a portion of the first conductive layer 221 in the stress-fragile area SC may be greater than a thickness t2′ of another portion of the first conductive layer 221.

The first conductive layer 221 may be formed by radiating laser to a layer including an organic material, and by adjusting the number, positions, and outputs of radiation of the laser, the thickness t1′ of the portion of the first conductive layer 221 may be greater than the thickness t2′ of the other portion of the first conductive layer 221.

in an embodiment, as illustrated in FIG. 8A, the layer including the organic material for forming the first conductive layer 221 includes the substrate 100 and/or the first organic insulating layer OL1. According to the number, the position, and the output of the radiation of the laser, the substrate 100 and/or the first organic insulating layer OL1 may include a concave recess as shown in FIG. 8A, and a portion of the first conductive layer 221 may be in the recess. A thickness TH1 of a portion of the substrate 100 and/or the first organic insulating layer OL1 corresponding to the recess may be less than a thickness TH2 of another portion of the substrate 100 and/or the first organic insulating layer OL1. Although FIG. 8A illustrates an embodiment where only one recess is provided in the stress-fragile area SC, in an alternative embodiment, the substrate 100 and/or the first organic insulating layer OL1 may include a plurality of recesses, and accordingly, the first conductive layer 221 of the wiring WL may include a plurality of portions having the aforementioned thickness t1′.

In an alternative embodiment, the layer including the organic material for forming the first conductive layer 221 may include a layer different from the substrate 100 and/or the first organic insulating layer OL1. The first conductive layer 221 may be formed by radiating a light such as laser on the layer including the organic material. The wiring WL may include the first conductive layer 221 and the second conductive layer 222, and the thickness t1′ of the portion of the first conductive layer 221 in the stress-fragile area SC may be greater than the thickness t2′ of the other portion of the first conductive layer 221. In an embodiment, as shown in FIG. 8B, the substrate 100 and/or the first organic insulating layer OL1 arranged under the wiring WL may have a relatively uniform thickness.

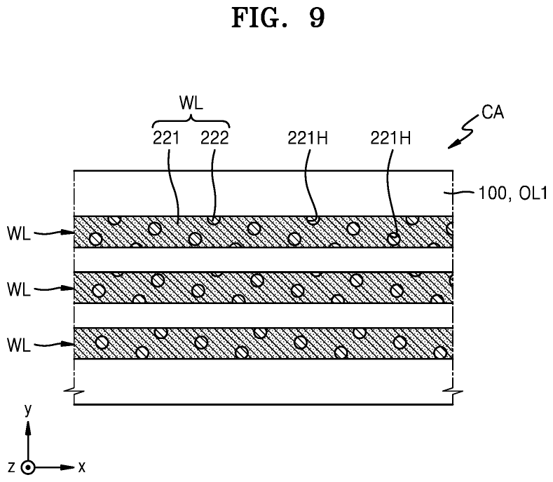

FIG. 9 is a top-plan view of an extracted image of the connection portion CA of the display device according to an embodiment of the disclosure.

Referring to FIG. 9, the plurality of wirings WL may be arranged apart from one another in the connection portion CA. The plurality of wirings WL may be arranged apart from one another by a distance of about at least 1 micrometer (μm). Each of the wirings WL may have a width in a range of about 0.1 μm to about 100 μm. Each of the wirings WL may include the first conductive layer 221 and the second conductive layer 222. The first conductive layer 221 of each of the wirings WL may be provided with a plurality of holes (hereinafter, referred to as pattern holes 221H) apart from one another when seen from top or when viewed in a top plan view (i.e., when viewed in a direction perpendicular to the substrate 100, e.g., −z direction).

In an embodiment where the first conductive layer 221 is provided with the pattern holes 221H, each of the pattern holes 221H is transformed when the display device 1 is elongated, and thus, the impact resistance of the wiring WL may be further improved. In an embodiment, for example, the pattern holes 221H may be arranged apart from another and may be arranged in a regular or an irregular manner. The second conductive layer 222 may overlap the pattern holes 221H of the first conductive layer 221.

According to embodiments of the disclosure, damage to the wiring arranged in the display device due to external force applied to the display device may be reduced or minimized.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A stretchable display device comprising:
a substrate comprising a first island area and a second island area, which are spaced apart from each other, and a connection area connected between the first island area and the second island area;
a first subpixel circuit disposed in the first island area;
a second subpixel circuit disposed in the second island area;
a first light-emitting diode disposed in the first island area and electrically connected to the first subpixel circuit;
a second light-emitting diode disposed in the second island area and electrically connected to the second subpixel circuit; and
a wiring disposed on the connection area and electrically connected to the first subpixel circuit and the second subpixel circuit,
wherein the wiring comprises:
a first conductive layer comprising a conductive organic material; and
a second conductive layer disposed on the first conductive layer and comprising a material different from a material of the first conductive layer.

2. The stretchable display device of claim 1, wherein the first conductive layer comprises a material having higher electrical conductivity than electrical conductivity of the material of the second conductive layer.

3. The stretchable display device of claim 2, wherein the first conductive layer comprises a conductive porous carbon material.

4. The stretchable display device of claim 2, wherein
the first conductive layer comprises a laser-induced carbon material, and
the second conductive layer comprises at least one material selected from aluminum (Al), copper (Cu), titanium (Ti), platinum (Pt), and gold (Au).

5. The stretchable display device of claim 4, further comprising:
an organic insulating layer disposed under the wiring in the connection area.

6. The stretchable display device of claim 5, wherein at least a portion of the wiring directly contacts the organic insulating layer.

7. The stretchable display device of claim 6, wherein a thickness of a first portion of the organic insulating layer overlapping the wiring is less than a thickness of a second portion of the organic insulating layer which does not overlap the wiring.

8. The stretchable display device of claim 5,
wherein a portion of the organic insulating layer extends onto an inorganic insulating layer disposed on the first island area, and
the organic insulating layer comprises a step portion near an edge of the inorganic insulating layer.

9. The stretchable display device of claim 8, wherein a thickness of a first portion of the first conductive layer on the step portion of the organic insulating layer is greater than a thickness of a second portion of the first conductive layer apart from the step portion.

10. The stretchable display device of claim 8,
wherein the organic insulating layer is provided with a contact hole defined therethrough in the first island area, and
the wiring is electrically connected to the first subpixel circuit through the contact hole.

11. The stretchable display device of claim 10, wherein a portion of the first conductive layer of the wiring is in the contact hole.

12. The stretchable display device of claim 1, wherein at least a portion of the wiring directly contacts the substrate.

13. The stretchable display device of claim 12, wherein the substrate comprises an insulating polymer.

14. The stretchable display device of claim 1, wherein, when viewed in a direction perpendicular to the substrate, the first conductive layer of the wiring is provided with a plurality of pattern holes apart from each other.

15. The stretchable display device of claim 1, wherein the wiring comprises a scan line, a data line, or a voltage line electrically connected to the first subpixel circuit and the second subpixel circuit.

16. The stretchable display device of claim 1,
wherein the connection area comprises a first area having a relatively high strain rate and a second area having a relatively low strain rate when the stretchable display device is elongated, and
a thickness of a portion of the wiring in the first area is greater than a thickness of another portion of the wiring in the second area.

17. The stretchable display device of claim 16, wherein the first area of the connection area comprises a middle point of a longitudinal portion of the connection area.

18. The stretchable display device of claim 17, wherein, when viewed in a direction perpendicular to the substrate, the connection area comprises a bent area, and the first area of the connection area further comprises the bent area.
